(19) United States
(12) Patent Application Publication
(10) Pub. No.: US 2004/0077173 A1
(43) Pub. Date: Apr. 22, 2004

(54) Using water soluble bottom anti-reflective coating

(76) Inventor: Swaminathan Sivakumar, Portland, OR (US)

Correspondence Address: Timothy N. Trop, TROP, PRUNER & HU, P.C., STE 100, 8554 KATY FWY, HOUSTON,, TX, 77024-1841, US

(21) Appl. No.: 10/273,077

(22) Filed: Oct. 17, 2002

(51) Int. Cl. H01L 21/311; H01L 21/302; H01L 21/461; H01L 21/31; H01L 21/469

(52) U.S. Cl. 438/694; 438/700; 438/717; 438/725; 438/780; 438/782; 438/952

(57) ABSTRACT

By making a bottom anti-reflective coating that is soluble in aqueous solutions, the bottom anti-reflective coating may be removed in the same process used to remove the exposed photoresist. This may reduce defects and poor selectivity to photoresist in some embodiments during the etching of the bottom anti-reflective coating and avoids the need to separately etch the exposed bottom anti-reflective coating in some embodiments.

### BACKGROUND

This invention relates generally to the manufacture of semiconductor integrated circuits and, particularly, to bottom anti-reflective coatings utilized in semiconductor manufacturing.

In the course of manufacturing semiconductor integrated circuits, patterns may be transferred from a mask to a photoresist. As a result of exposure to radiation, the photoresist may have regions that are chemically altered to correspond to the pattern on an exposure mask. These altered regions may then be selectively removed using etching processes to effectively transfer the pattern on the mask to the photoresist. The pattern in the photoresist may then be utilized as a pattern for selective removal of materials in underlying substrates below the photoresist.

A bottom anti-reflective coating may be placed under the exposed photoresist regions. Generally, advanced photoresist performance is optimized by the resist manufacturer on organic bottom anti-reflective coating substrates. The bottom anti-reflective coating works on the principle of thin film interference, causing destructive interference between the incident radiation on the bottom anti-reflective coating and the light reflected from the substrate.

However, a disadvantage with standard bottom anti-reflective coatings is that they are difficult to etch cleanly. Moreover, existing organic bottom anti-reflective coatings have relatively poor selectivity to photoresist. This poor selectivity may result in high resist erosion rates during the bottom anti-reflective coating etch, resulting in poor etch profiles. This low selectivity may also result in micromasking defects caused by incomplete removal of the bottom anti-reflective coating during the subsequent substrate etch.

Thus, there is a need for better ways to form bottom anti-reflective coatings.

### BRIEF DESCRIPTION OF THE DRAWINGS

FIG. 1 is an enlarged, schematic cross-sectional view of one embodiment of the present invention at an early stage of manufacture;

FIG. 2 is an enlarged cross-sectional view at a subsequent stage of manufacture in accordance with one embodiment of the present invention;

FIG. 3 is an enlarged cross-sectional view at a subsequent stage of manufacture; and

FIG. 4 is an enlarged cross-sectional view at a subsequent stage of manufacture in accordance with one embodiment of the present invention.

### DETAILED DESCRIPTION

A bottom anti-reflective coating (BARC) may be easily removed and defects and selectivity issues may be resolved, in some embodiments, by making the bottom anti-reflective coating soluble in an aqueous solution, like a developer, utilized to develop the photoresist or water. The bottom anti-reflective coating under the exposed photoresist regions may then be developed away during the develop process. This may reduce the need to etch the exposed bottom anti-reflective coating, avoiding the problems related to etching the bottom anti-reflective coating, such as defects and poor selectivity to photoresist, in some cases.

In order to make a bottom anti-reflective coating that is water soluble, the bottom anti-reflective coating should be soluble in an aqueous solution, such as a developer or water, enabling it to be removed in exposed areas in a standard developed process. The coating may be spun-on at odd multiples of one-quarter wavelength of light to ensure interference with the incident light.

In some embodiments the bottom anti-reflective coating may be formed of any water soluble polymer. For example, any of the water soluble polymers used to make water soluble photoresists, including casein, polyvinyl alcohol and fish glue, may be used.

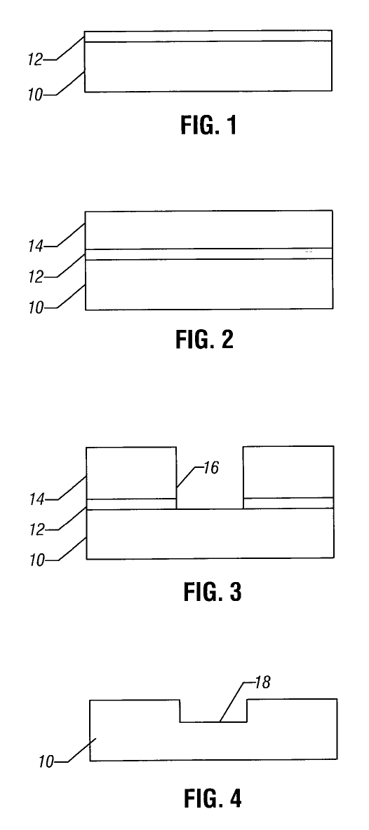

Referring to FIG. 1, a substrate 10, such as a semiconductor substrate, may be coated with a bottom anti-reflective coating 12. As shown in FIG. 2, the coating 12 may then be covered with a photoresist layer 14. In one embodiment the photoresist layer 14 may be spun-on. Any conventional photoresist material may be utilized.

Referring to FIG. 3, the photoresist may be patterned to form the aperture 16 that may extend, not only through the photoresist 14, but also through the bottom anti-reflective coating 12. This is because the developer used to develop the exposed photoresist 14 also attacks and removes the bottom anti-reflective coating 12 in the exposed region. As a result, the aperture 16 may be a relatively clean opening, in some embodiments, down to the substrate 10.

Thereafter, conventional etching techniques may be utilized to transfer the pattern in the photoresist layer 14 to the substrate 10 as shown in FIG. 4 at 18. Then the photoresist 14 and the bottom anti-reflective coating 12 may be removed in the same process utilized to remove the photoresist, eliminating the need for an extra step to remove the bottom anti-reflective coating 12.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
applying a bottom anti-reflective coating that is water soluble; and
forming a photoresist over said bottom anti-reflective coating.

2. The method of claim 1 including patterning the photoresist and the bottom anti-reflective coating at the same time.

3. The method of claim 2 including developing the photoresist and in the course of developing the photoresist removing a portion of the bottom anti-reflective coating.

4. The method of claim 1 including spinning-on the bottom anti-reflective coating at odd multiples of one-quarter wavelength of the light used to expose the photoresist.

5. A semiconductor structure comprising:
a semiconductor support; and
a bottom anti-reflective coating on said support, said coating being soluble in an aqueous solution.

6. The structure of claim 5 including a photoresist over said bottom anti-reflective coating.

7. The structure of claim 5 wherein said anti-reflective coating is a water soluble polymer.

8. A method comprising:
forming a water soluble bottom anti-reflective coating;
covering said coating with a photoresist;
developing said photoresist in a pattern; and
removing a portion of said coating while developing said photoresist.

9. The method of claim 8 including spinning on said bottom anti-reflective coating.

10. The method of claim 8 including applying said coating in a plurality of layers that are odd multiples of one-quarter wavelength of the light used to expose the photoresist.

11. A method comprising:
developing a photoresist; and
removing a bottom anti-reflective coating while developing said photoresist.

12. The method of claim 11 including applying a water soluble bottom anti-reflective coating.

13. The method of claim 11 including forming the photoresist over said bottom anti-reflective coating.

14. The method of claim 11 including applying a water soluble polymer as said anti-reflective coating.

15. The method of claim 14 including spinning on said bottom anti-reflective coating at odd multiples of one-quarter wavelength of the light used to expose the photoresist.
